(19) United States
(12) Patent Application Publication
(10) Pub. No.: US 2005/0051895 A1
(43) Pub. Date: Mar. 10, 2005

(54) BGA package having semiconductor chip with edge-bonding metal patterns formed thereon and method of manufacturing the same

(75) Inventors: Byoung-Chan Kim, Chungchungbuk-do (KR); Young-Hwan Shin, Daejeon (KR); Kyoung-Ro Yoon, Daejeon (KR)

Correspondence Address: MORGAN LEWIS & BOCKIUS LLP, 1111 PENNSYLVANIA AVENUE NW, WASHINGTON, DC, 20004, US

(73) Assignee: Samsung Electro-Mechanics Co., Ltd.

(21) Appl. No.: 10/720,484

(22) Filed: Nov. 25, 2003

(30) Foreign Application Priority Data
Sep. 4, 2003 (KR) 2003-61812

(51) Int. Cl. H01L 23/48; H01L 21/44

(52) U.S. Cl. 257/738; 257/737; 257/698; 257/777; 438/613

(57) ABSTRACT

The present invention relates to a BGA package having center-bonding type semiconductor chips with edge-bonding metal patterns formed thereon wherein the edge-bonding metal patterns are formed on the semiconductor chips in a wafer level, and wire bonding is carried out in the shape of edge bonding so that a plurality of semiconductor chips are stacked, whereby high-density memory performance is obtained, and a method of manufacturing the same.

### BACKGROUND OF THE INVENTION

1. Field of the Invention

The present invention relates to a ball grid array (hereinafter, referred to as “BGA”) package having a semiconductor chip with edge-bonding metal patterns formed thereon in a wafer level and a method of manufacturing the same.

More particularly, the present invention relates to a BGA package having center-bonding type semiconductor chips with edge-bonding metal patterns formed thereon wherein the edge-bonding metal patterns are formed on the semiconductor chips in a wafer level, and wire bonding is carried out in the shape of edge bonding so that a plurality of semiconductor chips are stacked, whereby high-density memory performance is obtained, and a method of manufacturing the same.

2. Description of the Related Art

Commonly used BGA packages are generally classified into a center-bonding pad type BGA package and an edge-bonding pad type BGA package depending upon where a bonding pad formed on a semiconductor chip mounted to a BGA substrate is located.

The center-bonding pad type BGA package, which has a chip pad placed on the center of a semiconductor chip as shown in FIG. 1, is generally used to facilitate chip design of semiconductor products and improve the electrical characteristics of the semiconductor chip in a wafer level.

A brief description of the conventional BGA package 100 having such a center-bonding pad will be given with reference to FIG. 1. At the center of the active surface of a chip 1 is formed a chip pad 3, and on the inactive surface of the chip 1 is applied a bonding agent 7. The chip 1 is attached to a substrate 1 by means of the bonding agent 7. On the upper surface of the substrate 2 are formed substrate pads 9, and on the lower surface of the substrate 2 are formed a plurality of solder pads 8. On the entire lower surface of the substrate 2 excluding the solder pads 8 is applied a photoresist. To the substrate 2 is attached a plurality of the solder balls 5 via the corresponding solder pads 8.

Between the chip pad 3 and the substrate pad 9 are joined bonding wires 4, which electrically connect the chip 1 and the substrate 2. On the substrate 2 is formed molding resin 6, which protect the chip 1 and the bonding wires 4 on the substrate 2 from the external environment.

The center-bonding pad type BGA package 100 can be easily manufactured as described above. However, it is required that each of the bonding wires 4 has a great length since the distance between the chip pad 3 and the substrate pad 9 is very long. As a result, the bonding wires are biased in the molding direction due to the molding pressure when the chip is molded with the aforesaid molding resin with the result that there occurs easy sweeping of the bonding wires 4, by which the chip has a short circuit at the edge thereof. Consequently, stability of the bonding wires 4 is decreased.

In order to solve the above-mentioned problem, several BGA packages have been proposed, one of which is disclosed in Korean Patent Application No. 10-2001-0078134 entitled “CENTER PAD TYPE BGA PACKAGE HAVING CHIP WITH METAL PATTERNS FORMED THEREON,” which will be hereinafter described with reference to FIG. 2.

As shown in FIG. 2, the center pad type BGA package comprises: a chip 31 having a chip pad 33 formed on the center of the active surface thereof, and a plurality of metal patterns 40 formed around the chip pad 33 on the active surface thereof; a substrate 32 having substrate pads 39 formed on the upper surface thereof, and a plurality of solder pads 38 formed on the lower surface thereof, the chip 31 being attached to the substrate 32 by means of a bonding agent 37 applied to the inactive surface of the chip 31; first bonding wires 341 for electrically connecting the chip pad 33 and the metal patterns 40 to each other; second bonding wires 342 for electrically connecting the metal patterns 40 and the substrate pads 39 to each other; a plurality of solder balls 35 attached to the substrate 32 via the corresponding solder pad 38; and molding resin 36 formed in the substrate 32 for protecting the chip 31, the first bonding wires 341 and the second bonding wires 342 on the substrate 32.

The lengths of the bonding wires of the center pad type BGA package as shown in FIG. 2 are smaller than those of the bonding wires of the BGA package as shown in FIG. 1. Consequently, the problem that there occurs easy sweeping of the bonding wires is solved using the center pad type BGA package having the chip with the metal patterns formed thereon as shown in FIG. 2. However, the center pad type BGA package still has problems in that the manufacturing process is complicated since the first bonding wires are required to connect the chip pad and the metal patterns and in that the bonding wires are easily broken.

Furthermore, it is not possible to stack one chip on another chip due to the first bonding wires for connecting the chip pad and the metal patterns, and thus it is not possible to realize a BGA package having high-density memory performance.

### SUMMARY OF THE INVENTION

Therefore, the present invention has been made in view of the above problems, and it is an object of the present invention to provide a BGA package having center-bonding type semiconductor chips with edge-bonding metal patterns formed thereon wherein the edge-bonding metal patterns are formed on the semiconductor chips in a wafer level, and wire bonding is carried out in the shape of edge bonding so that a plurality of semiconductor chips are stacked, whereby high-density memory performance is obtained, and a method of manufacturing the same.

It is another object of the present invention to provide a BGA package having center-bonding type semiconductor chips with edge-bonding metal patterns formed thereon wherein the edge-bonding metal patterns are formed on the semiconductor chips in a wafer level so that disconnection of wires and short circuits generated in the course of wire bonding are prevented, whereby reliability of the package is improved, and a method of manufacturing the same.

It is yet another object of the present invention to provide a BGA package having center-bonding type semiconductor chips with edge-bonding metal patterns formed thereon wherein the edge-bonding metal patterns are formed on the semiconductor chips in a wafer level so that wire bonding pads for electrical connection can be miniaturized, whereby the cost of manufacturing semiconductor chips is reduced, and a method of manufacturing the same.

In accordance with one aspect of the present invention, the above and other objects can be accomplished by the provision of a BGA package having a semiconductor chip with edge-bonding metal patterns formed thereon, comprising: a substrate having circuit patterns for electric connection formed therein; a center-bonding type semiconductor chip attached to the substrate, the semiconductor chip having center-bonding pads formed on one side thereof; edge-bonding metal patterns electrically connected to the center-bonding pads of the semiconductor chip, the edge-bonding metal patterns being extended towards the edge regions of the center-bonding type semiconductor chip; connection members for electrically connecting the edge-bonding metal patterns extended towards the edge regions of the semiconductor chip to the circuit patterns of the substrate, respectively; a sealing material for molding the substrate to protect the semiconductor chip; and solder balls attached to solder pads electrically connected to the circuit patterns of the substrate, respectively, for transmitting electric signals from the semiconductor chip to an external substrate.

In accordance with another aspect of the present invention, there is provided a BGA package having semiconductor chips with edge-bonding metal patterns formed thereon, comprising: a substrate having circuit patterns for electric connection formed therein; a first center-bonding type semiconductor chip attached to the substrate, the first semiconductor chip having center-bonding pads formed on one side thereof; edge-bonding metal patterns electrically connected to the center-bonding pads of the first semiconductor chip, the edge-bonding metal patterns being extended towards the edge regions of the first center-bonding type semiconductor chip; a bonding member applied to the first semiconductor chip to form a stacked structure; a second center-bonding type semiconductor chip stacked on the first semiconductor chip via the bonding member, the second semiconductor chip having center-bonding pads formed on one side thereof; edge-bonding metal patterns electrically connected to the center-bonding pads of the second semiconductor chip, the edge-bonding metal patterns being extended towards the edge regions of the second center-bonding type semiconductor chip; connection members for electrically connecting the edge-bonding metal patterns of the first and second semiconductor chips to the circuit patterns of the substrate, respectively; a sealing material for molding the substrate to protect the first and second semiconductor chips; and solder balls attached to solder pads electrically connected to the circuit patterns of the substrate, respectively, for transmitting electric signals from the first and second semiconductor chips to an external substrate.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a sectional view showing the structure of a conventional BGA package with center-bonding pads;

FIG. 2 is a sectional view showing the structure of another conventional center pad type BGA package having a semiconductor chip with metal patterns formed thereon;

FIG. 3 is a sectional view of a single-layered BGA package having a semiconductor chip with edge-bonding metal patterns formed thereon according to a first preferred embodiment of the present invention;

FIGS. 4a to 4i are process diagrams showing the steps for forming the edge-bonding metal patterns on the semiconductor chip according to the first preferred embodiment of the present invention;

FIG. 5 is a flow chart showing a method of manufacturing a single-layered BGA package having a semiconductor chip with edge-bonding metal patterns formed thereon according to a first preferred embodiment of the present invention;

FIG. 6 is a flow chart showing the steps for forming the edge-bonding metal patterns on the semiconductor chip according to the first preferred embodiment of the present invention;

FIG. 7 is a sectional view of a multi-layered BGA package having semiconductor chips with edge-bonding metal patterns formed thereon according to a second preferred embodiment of the present invention; and

FIG. 8 is a flow chart showing a method of manufacturing a multi-layered BGA package having semiconductor chips with edge-bonding metal patterns formed thereon according to a second preferred embodiment of the present invention.

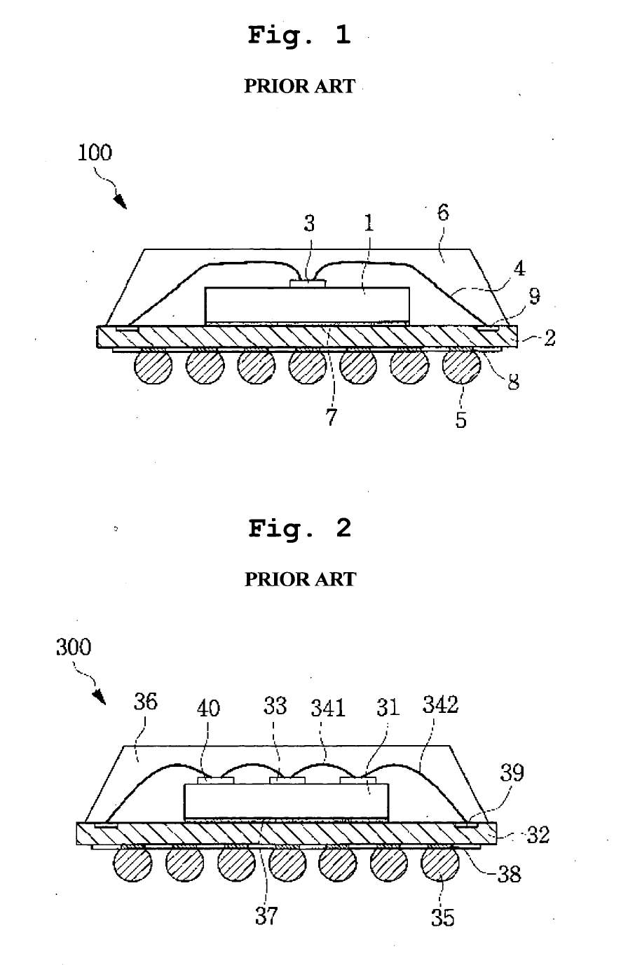

### DESCRIPTION OF THE PREFERRED EMBODIMENTS

Now, a detailed description will be given of a BGA package having a semiconductor chip with edge-bonding metal patterns formed thereon in a wafer level according to the present invention and a method of manufacturing the same with reference to the accompanying drawings.

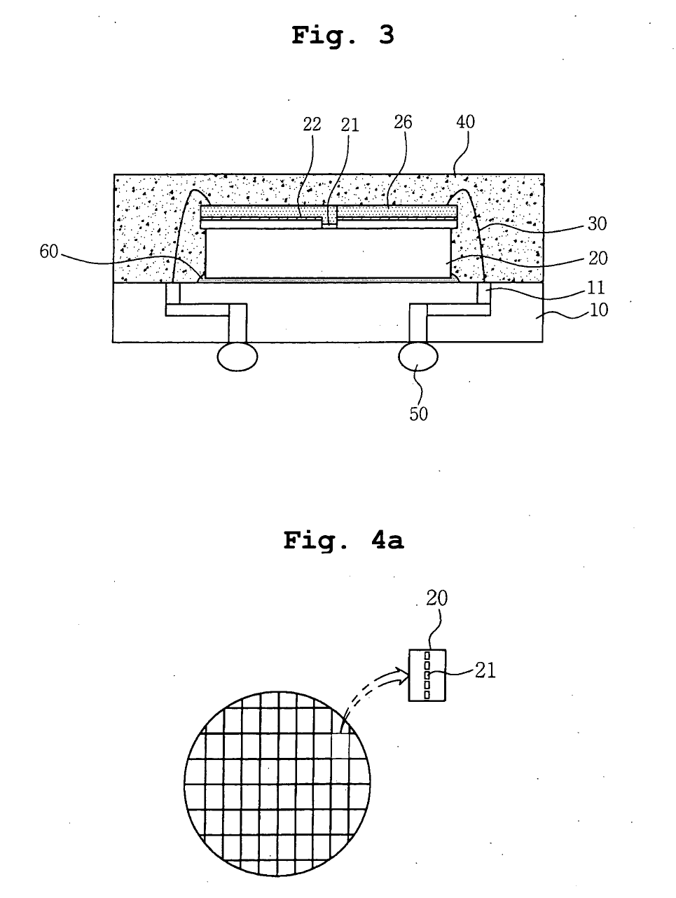

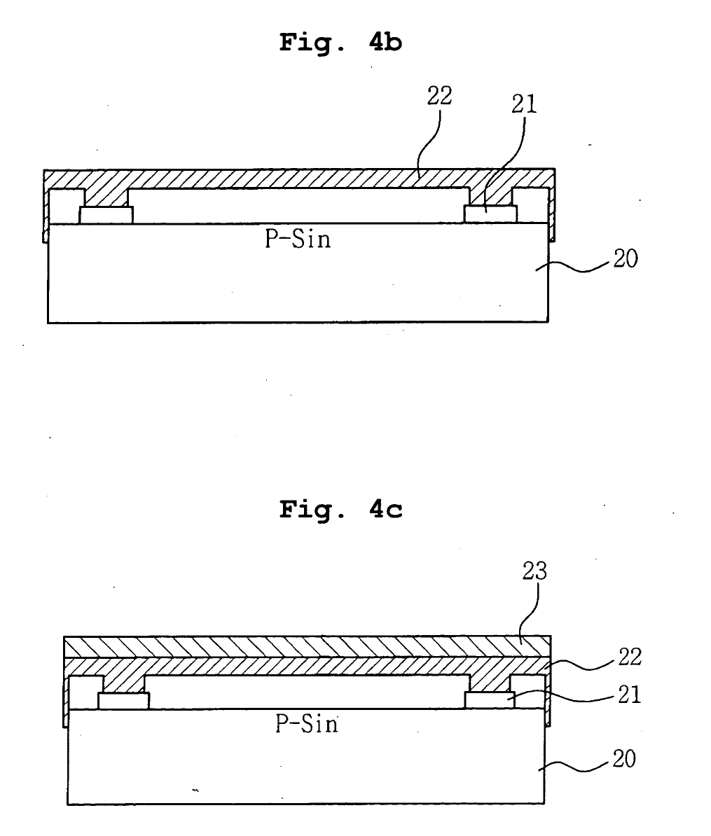

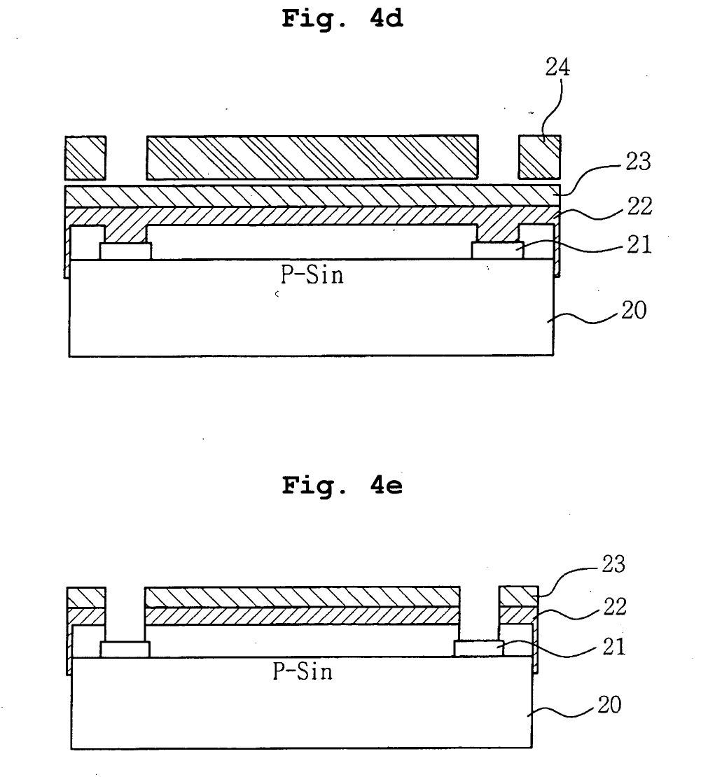

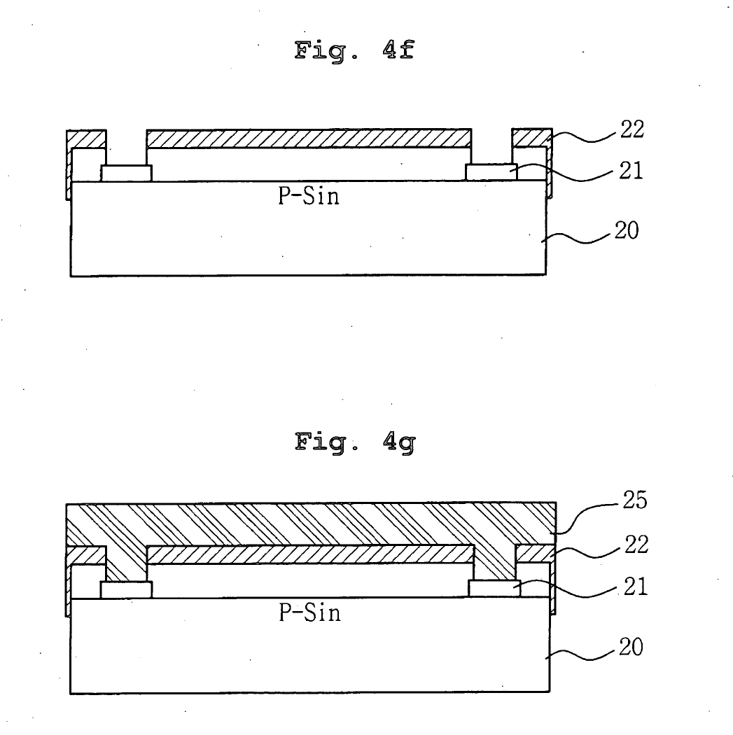

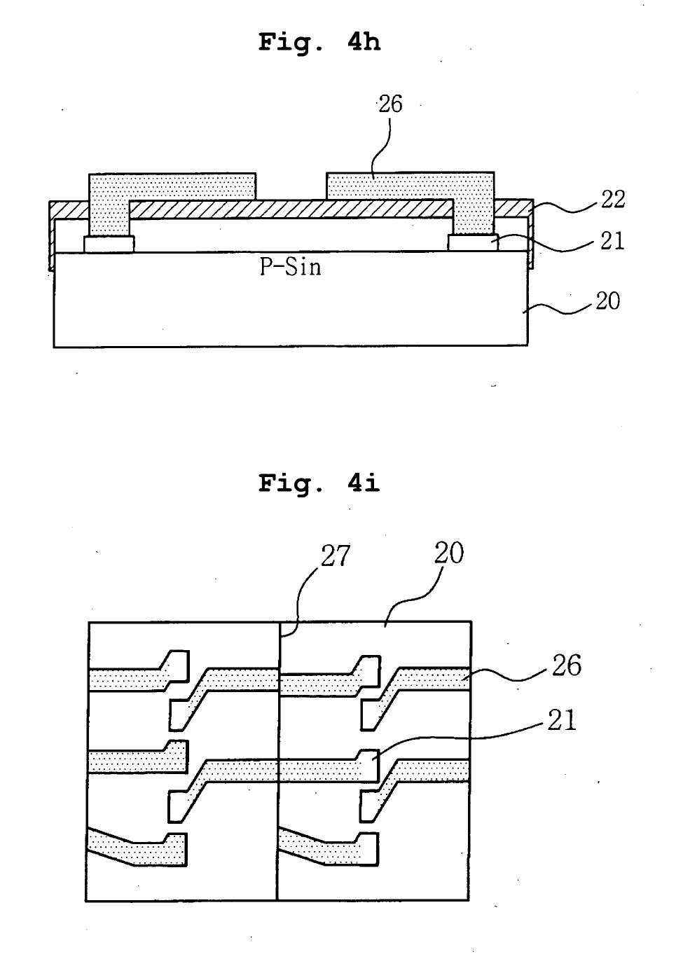

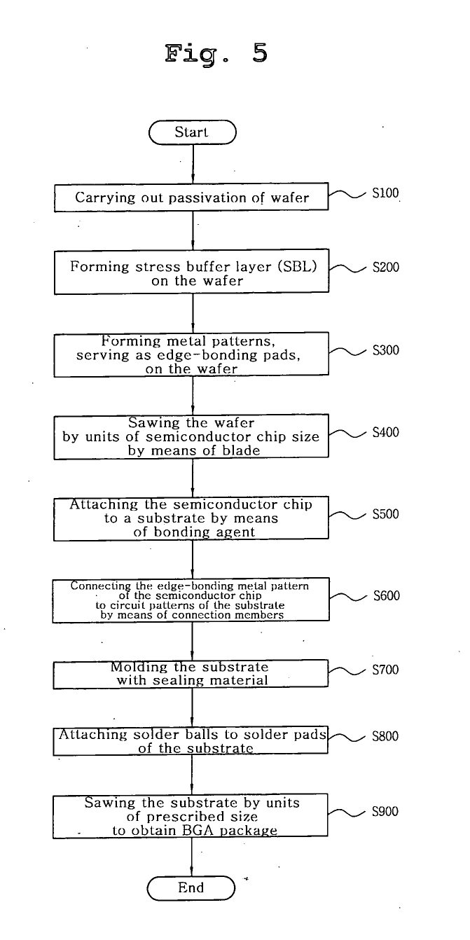

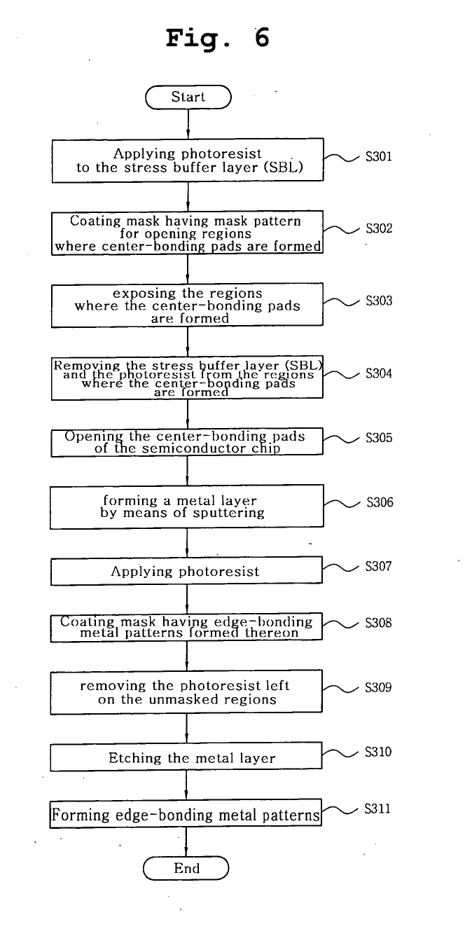

FIG. 3 is a sectional view of a single-layered BGA package having a semiconductor chip with edge-bonding metal patterns formed thereon according to a first preferred embodiment of the present invention, FIGS. 4a to 4i are process diagrams showing the steps for forming the edge-bonding metal patterns on the semiconductor chip according to the first preferred embodiment of the present invention, FIG. 5 is a flow chart showing a method of manufacturing a single-layered BGA package having a semiconductor chip with edge-bonding metal patterns formed thereon according to a first preferred embodiment of the present invention, and FIG. 6 is a flow chart showing the steps for forming the edge-bonding metal patterns on the semiconductor chip according to the first preferred embodiment of the present invention.

Referring to FIG. 3, the construction of the single-layered BGA package having the semiconductor chip with the edge-bonding metal patterns formed thereon in a wafer level according to the first preferred embodiment of the present invention will be first described in detail.

First Preferred Embodiment

The single-layered BGA package having the semiconductor chip with the edge-bonding metal patterns formed thereon in a wafer level according to the first preferred embodiment of the present invention comprises a substrate 10, a semiconductor chip 20, connection members 30, a sealing material 40, solder balls 50, and a bonding agent 60, as shown in FIG. 3.

The substrate 10 is a rigid or flexible BGA substrate having circuit patterns 11 for electrical connection with the outside formed therein. On the upper surface of the substrate 10 is mounted the semiconductor chip 20 by means of the bonding agent 60. On the semiconductor chip 20 are formed edge-bonding metal patterns 26, which will be described later. The edge-bonding metal patterns 26 are electrically connected to the corresponding circuit patterns 11 by means of the connection members 30.

On the lower surface of the substrate 10 are formed solder pads (not shown), which are electrically connected to the circuit patterns 11 of the substrate 10. The solder balls 50, which are provided for electrical connection with an external substrate, are attached to the solder pads, respectively. Electric signals from the semiconductor chip 20 are transmitted to the outside through the solder balls 50 attached to the solder pads, which will be described later.

The semiconductor chip 20 is a center-bonding type semiconductor chip having center-bonding pads formed on the upper surface thereof as shown in FIG. 4i. On the semiconductor chip 20 are formed edge-bonding metal patterns 26, which are electrically connected to the center-bonding pads 21 of the semiconductor chip 20 in a wafer level by means of a prescribed process, for example, sputtering. The edge-bonding metal patterns 26 are extended towards the edge regions of the center-bonding type semiconductor chip so that they are also electrically connected to the corresponding circuit patterns 11 of the substrate 10 be means of the connection members 30. The semiconductor chip is mounted on the substrate 10 by means of the bonding agent 60.

The edge-bonding metal patterns 26 of the semiconductor chip 20 are electrically connected to the circuit patterns 11 of the substrate 10 by means of the connection members 30, respectively.

The process for forming the edge-bonding metal patterns 26 on the semiconductor chip in a wafer level will now be described with reference to FIGS. 4a to 4c.

First of all, in order to change the center-bonding type semiconductor chip 30 having the center-bonding pads 21 formed on the center thereof into an edge-bonding type semiconductor chip, passivation of the semiconductor wafer with the center-bonding type semiconductor chip 20 as shown in FIG. 4a is carried out so that the surface of the semiconductor wafer is stabilized.

The passivation is carried out to stabilize the surface of the semiconductor wafer. P₂O₆, as a getter, is attached on the oxide film of the semiconductor wafer to prevent Na ions from entering into the oxide film of the semiconductor wafer in the course of a heat-treating process. Consequently, the semiconductor chip formed on the wafer is protected.

After the passivation of the semiconductor wafer is carried out as described above, a stress buffer layer (SBL) 22 is coated on the semiconductor wafer, as shown in FIG. 4b.

The stress buffer layer 22 prevents isolation between a fuse box of the semiconductor chip 20 and a metal layer, which will be described later. Also, the stress buffer layer 22 minimizes damage to the semiconductor chip in the course of wire bonding.

After the stress buffer layer 22 is coated on the semiconductor wafer as described above, a photoresist 23, which is a photosensitive material, is applied to the stress buffer layer 22 to open the center-bonding pads 21 of the semiconductor chip 20, as shown in FIG. 4c.

On the photoresist 23 is subsequently coated a mask 24 having a mask pattern for opening the regions of the semiconductor chip 20 at which the center-bonding pads 21 are formed, as shown in FIG. 4d.

After the masking process is carried out as described above, the unmasked regions, i.e., the regions of the semiconductor chip 20 at which the center-bonding pads 21 are formed are exposed as shown in FIG. 4e. The exposed regions, i.e., the regions that are not masked by means of the mask 24 are developed to remove the stress buffer layer 22 and the photoresist 23 from the unmasked regions.

After removing the stress buffer layer 22 and the photoresist 23 from the unmasked regions as described above, the photoresist 23 on the masked regions, i.e., on the unexposed regions is exfoliated to open the center-bonding pads 21 of the semiconductor chip 20, as shown in FIG. 4f.

Subsequently, a metal layer 25 is formed on the semiconductor chip 20 by means of sputtering so as to form edge-bonding metal patterns on the semiconductor chip 20, as shown in FIG. 4g.

The metal layer 25 is electrically connected to the center-bonding pads 21 of the semiconductor chip 20 by means of sputtering.

After the metal layer 25 is formed on the semiconductor chip 20 as described above, edge-bonding metal patterns 26 are formed which serve as edge-bonding pads with a prescribed shape electrically connected to the center-bonding pads 21 of the semiconductor chip 20, as shown in FIG. 4h.

Specifically, a photoresist is applied to the metal layer 25, and a mask having a mask pattern for forming the edge-bonding metal patterns 26 is coated on the photoresist.

Subsequently, the photoresist on the regions that are not masked by means of the mask is exposed so that the photoresist on the exposed regions is removed, and the metal layer 25 under the removed photoresist is etched.

After the metal layer 25 under the removed photoresist is etched as described above, the photoresist left on the unexposed regions, i.e., on the regions protected by the mask, is exfoliated to form the edge-bonding metal patterns 26 on the semiconductor chip 20 as shown in FIG. 4i.

FIG. 4i is a plan view of the semiconductor chip having the edge-bonding metal patterns 26 extended from the center-bonding pads 21 to the edge regions of the semiconductor chip. Reference numeral 27 indicates a sawing line along which the semiconductor chip having edge-bonding metal patterns formed thereon is cut to obtain separate semiconductor chips.

The connection members 30 electrically connect the substrate 10 and the semiconductor chip 20 mounted on the substrate 10 to each other. Specifically, the circuit patterns 11 formed in the substrate 10 are electrically connected to the corresponding edge-bonding metal patterns 26, serving as the edge-bonding pads, formed on the semiconductor chip 20 mounted on-substrate 10 at the edge regions of the semiconductor chip 20 by means of the connection members 30.

Conductive wires are generally used as the connection members 30. It should be noted, however, that any other connection means may be used unrestrictedly to accomplish the technical idea of the present invention.

The sealing material 40 protects the semiconductor chip 20 mounted on the substrate 10 and the connection members 30, i.e., the conductive wires, which electrically connect the substrate 10 and the semiconductor chip 20.

Synthetic resin is mainly used as the sealing member 40 that molds the semiconductor chip 20 mounted on the substrate 10. It should be noted, however, that any other sealing material may be used unrestrictedly.

The solder balls 50 are attached to the corresponding solder pads (not shown) formed on the lower surface of the substrate 10. Electric signals from the semiconductor chip 20 mounted on the substrate 10 are transmitted to an external substrate by means of the solder balls 50.

More specifically, when prescribed electric signals are outputted from the edge-bonding metal patterns 26, serving as the edge-bonding pads, formed on the semiconductor chip 20, the electric signals are inputted to the circuit patterns 11 formed in the substrate 10 via the connection members 30.

Subsequently, the electric signals inputted to the circuit patterns 11 are supplied to the solder pads, which are electrically connected to the circuit patterns 11. The electric signals supplied to the solder pads are transmitted to an external substrate via the solder balls 50.

Now, a method of manufacturing a single-layered BGA package having a semiconductor chip with edge-bonding metal patterns formed thereon in a wafer level according to a first preferred embodiment of the present invention will be described in detail with reference to FIG. 5.

First, passivation of the wafer having the semiconductor chip 20 with the center-bonding pads 21 formed thereon is carried out (S100).

Specifically, P₂O₆ is attached on the oxide film of the wafer having the semiconductor chip 20 to prevent Na ions from entering into the oxide film of the wafer in the course of a heat-treating process so that damage to the semiconductor chip is prevented.

After the passivation of the wafer is carried out as described above, an isolating process is carried out between the fuse box of the semiconductor chip 20 and the metal layer 25. The stress buffer layer 22 is coated on the wafer for minimizing damage to the semiconductor chip 20 in the course of wire bonding (S200).

Subsequently, the wafer having the stress buffer layer 22 formed thereon, is patterned by means of a prescribed masking process to realize the semiconductor chip 20 having the edge-bonding metal patterns 26, serving as the edge-bonding pads, on the wafer (S300).

The step S300 of realizing the semiconductor chip 20 having the edge-bonding metal patterns 26, serving as the edge-bonding pads, on the wafer will be hereinafter described in detail with reference to FIG. 6.

First, the photosensitive material, for example, the photoresist 23 is applied to the stress buffer layer 22 to open the center-bonding pads 21 of the semiconductor chip 20 (S301), and the mask 24 having a mask pattern, which is provided for opening the regions at which the center-bonding pads 21 of the semiconductor chip 20 are formed, is coated on the photoresist 23 (S302).

After the photoresist 23 is masked as described above, the regions that are not masked by means of the mask, i.e., the regions at which the center-bonding pads 21 are formed are exposed (S303).

Subsequently, the exposed regions are developed to remove the photoresist 23 and the stress buffer layer 22 from the regions at which the center-bonding pads 21 of the semiconductor chip 20 are formed (S304), and the photoresist 23 on the regions masked by means of the mask, i.e., on the unexposed regions is exfoliated to open the center-bonding pads 21 of the semiconductor chip 20 (S305).

After the center-bonding pads 21 of the semiconductor chip 20 are opened as described above, the metal layer 25 is formed on the semiconductor chip 20 by means of a prescribed depositing process such as sputtering so as to form edge-bonding metal patterns 26 on the semiconductor chip 20 (S306).

Subsequently, a photoresist is applied to the metal layer 25 (S307), and the mask having the mask pattern, which is provided for forming the edge-bonding metal patterns 26 on the photoresist, is coated on the photoresist (S308).

After the mask is coated on the photoresist as described above, the photoresist on the regions that are not masked by means of the mask, i.e., on the regions at which the metal patterns are not formed, is removed (S309), and the metal layer 25 under the removed photoresist is etched to remove the metal layer 25 (S310).

Finally, the photoresist left on the unexposed regions, i.e., on the regions protected by the mask, is exfoliated to form the edge-bonding metal patterns 26 on the semiconductor chip 20 (S311).

After the semiconductor chip 20 having the edge-bonding metal patterns 26 formed thereon is realized on the wafer, the metal-patterned wafer is sawn by units of a prescribed semiconductor chip size by means of a blade (S400).

Subsequently, the semiconductor chip 20 having the edge-bonding metal patterns 26 formed thereon, which is sawn by units of the prescribed semiconductor chip size, is attached to the substrate 10 having the circuit patterns 11 formed therein, which are formed in a prescribed shape for electric connection, by means of the bonding agent 60 (S500).

After the semiconductor chip 20 is attached to the substrate 10 as described above, the edge-bonding metal patterns 26 formed on the semiconductor chip 20 and the circuit patterns 11 formed in the substrate 10 are connected to each other by means of the connection members 30, i.e., the conductive wires so that the edge-bonding metal patterns 26 formed on the semiconductor chip 20 are electrically connected to the corresponding circuit patterns 11 formed in the substrate 10 at the edge regions of the semiconductor chip 20 (S600).

Subsequently, the substrate 10 is molded with the sealing material 40, for example, synthetic resin to protect the semiconductor chip 20 formed on the substrate 10 (S700), and the solder balls 50 are attached to the conductive solder pads formed on the lower surface of the substrate 10 so that electric signals from the semiconductor chip 20 mounted on the substrate 10 are transmitted to an external substrate (S800).

Finally, the packaged substrate molded with the sealing material 40 is sawn by units of a prescribed size to obtain a BGA package having a semiconductor chip with the edge-bonding metal patterns 26 formed thereon in a wafer level (S900).

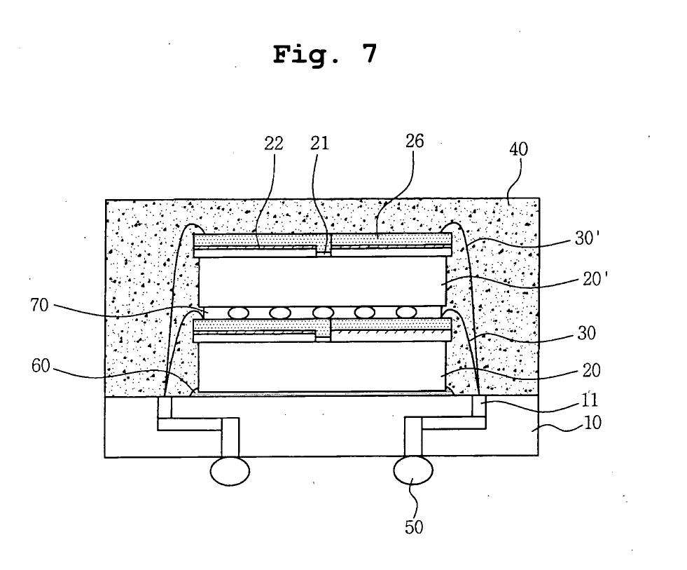

Now, a detailed description will be given of a multi-layered BGA package having semiconductor chips with edge-bonding metal patterns formed thereon in a wafer level according to a second preferred embodiment of the present invention with reference to FIG. 7.

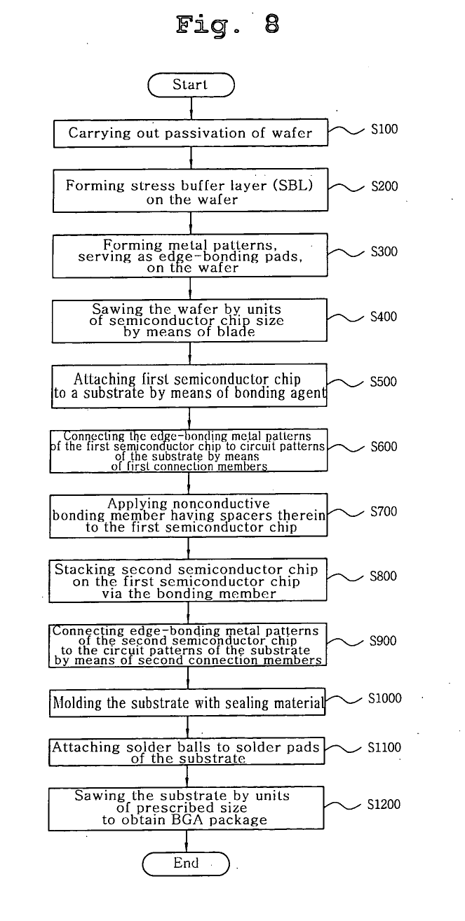

FIG. 7 is a sectional view of a multi-layered BGA package having semiconductor chips with edge-bonding metal patterns formed thereon in a wafer level according to a second preferred embodiment of the present invention, and FIG. 8 is a flow chart showing a method of manufacturing a multi-layered BGA package having semiconductor chips with edge-bonding metal patterns formed thereon in a wafer level according to a second preferred embodiment of the present invention.

It can be seen from FIG. 7 that the number of semiconductor chips in the multi-layered BGA package having semiconductor chips with edge-bonding metal patterns formed thereon in a wafer level is two. It should be noted, however, that more than two semiconductor chips may be used to accomplish the technical idea of the present invention.

Second Preferred Embodiment

The multi-layered BGA package having the semiconductor chips with the edge-bonding metal patterns formed thereon in a wafer level according to the second preferred embodiment of the present invention comprises: a substrate 10; a first semiconductor chip 20 and a second semiconductor chip 20′; first connection members 30 and second connection members 30′; a sealing material 40; solder balls 50; a bonding agent 60; and a bonding member 70, as shown in FIG. 7.

The substrate 10 is a rigid or flexible BGA substrate having circuit patterns 11 for electrical connection with the outside formed therein. On the upper surface of the substrate 10 are mounted the first semiconductor chip 20 and the second semiconductor chip 20′ by means of the bonding agent 60. On the first semiconductor chip 20 are formed edge-bonding metal patterns 26, which will be described later. Similarly, on the second semiconductor chip 20 are also formed edge-bonding metal patterns 26. The edge-bonding metal patterns 26 formed on the first semiconductor chip 20 are electrically connected to the corresponding circuit patterns 11 by means of the connection members 30. Similarly, the edge-bonding metal patterns 26 formed on the second semiconductor chip 20′ are also electrically connected to the corresponding circuit patterns 11 by means of the connection members 30′.

Between the second semiconductor chip 20′ and the first semiconductor chip 20 mounted on the substrate 10 is disposed the nonconductive bonding member 70 having spacers therein. The nonconductive bonding member 70 having the spacers therein serves to maintain balance between the first semiconductor chip 20 and the second semiconductor chip 20′.

The nonconductive bonding member 70 having the spacers therein also serves to prevent shorts between the second semiconductor chip 20′ and the connection members 30, i.e., the conductive wires of the first semiconductor chip 20.

On the lower surface of the substrate 10 are formed solder pads, which are electrically connected to the circuit patterns 11 of the substrate 10. The solder balls 50, which are provided for electrical connection with an external substrate, are attached to the solder pads, respectively. Electric signals from the first semiconductor chip 20 and the second semiconductor chip 20′ are transmitted to the outside through the solder balls 50 attached to the solder pads, which will be described later.

On each of the first semiconductor chip 20 and the second semiconductor chip 20′ are formed edge-bonding metal patterns 26, which are electrically connected to the center-bonding pads 21 in a wafer level by means of a prescribed process, for example, sputtering, as shown in FIG. 4i of the first preferred embodiment of the present invention. The edge-bonding metal patterns 26 are extended towards the edge regions of the respective semiconductor chips 20 and 20′.

The first and second semiconductor chips 20 and 20′ are mounted on the substrate 10 by means of the bonding agent 60. The edge-bonding metal patterns 26 are electrically connected to the corresponding circuit patterns 11 formed in the substrate 10 at the edge regions of the first and second semiconductor chips 20 and 20′ by means of the connection members 30 and 30′.

The process for forming the edge-bonding metal patterns 26 on the first and second semiconductor chips 20 and 20′ in a wafer level is the same as that according to the first preferred embodiment of the present invention, and therefore a detailed description thereof will not be given.

The first connection members 30 electrically connect the substrate 10 and the first semiconductor chip 20 mounted on the substrate 10 to each other. Similarly, the second connection members 30′ electrically connect the substrate 10 and the second semiconductor chip 20′ mounted on the substrate 10 to each other. Specifically, the circuit patterns 11 formed in the substrate 10 are electrically connected to the corresponding edge-bonding metal patterns 26 formed on the first and second semiconductor chips 20 and 20′ mounted on substrate 10 by means of the first and second connection members 30 and 30′.

Conductive wires are generally used as the connection members. It should be noted, however, that any other connection means may be used unrestrictedly to accomplish the technical idea of the present invention.

The sealing material 40 protects the first and second semiconductor chips 20 and 20′ mounted on the substrate 10 and the first and second connection members 30 and 30′, i.e., the conductive wires, which electrically connect the substrate 10 and the first and second semiconductor chips 20 and 20′, respectively.

Synthetic resin is mainly used as the sealing member 40 for molding the first and second semiconductor chips 20 and 20′ mounted on the substrate 10. It should be noted, however, that any other sealing material may be used unrestrictedly.

The solder balls 50 are attached to the corresponding solder pads formed on the lower surface of the substrate 10. Electric signals from the first and second semiconductor chips 20 and 20′ mounted on the substrate 10 are transmitted to an external substrate by means of the solder balls 50.

More specifically, when prescribed electric signals are outputted from the edge-bonding metal patterns 26 formed on the first and second semiconductor chip 20, the signals are inputted to the circuit patterns 11 formed in the substrate 10 via the connection members 30 connected to the first semiconductor chip 20 and via the connection members 30′ connected to the second semiconductor chip 20′.

Subsequently, the electric signals inputted to the circuit patterns 11 are supplied to the solder pads, which are electrically connected to the circuit patterns 11. The electric signals supplied to the solder pads are transmitted to an external substrate via the solder balls 50.

In the second preferred embodiment of the present invention, it has been described that the multi-layered BGA package has two stacked semiconductor chips. It should be noted, however, that the present invention is not limited to such a two-layered BGA package, and thus it may include multi-layered BGA packages having more than two stacked semiconductor chips.

Now, a method of manufacturing a multi-layered BGA package having a semiconductor chip with edge-bonding metal patterns formed thereon in a wafer level according to a second preferred embodiment of the present invention will be described in detail with reference to FIG. 8.

First, passivation of the wafer having the semiconductor chip 20 with the center-bonding pads 21 formed thereon is carried out (S100).

Specifically, P₂O₆ is attached on the oxide film of the wafer having the semiconductor chip 20 to prevent Na ions from entering into the oxide film of the wafer in the course of a heat-treating process so that damage to the semiconductor chip is prevented.

After the passivation of the wafer is carried out as described above, an isolating process is carried out between the fuse box of the semiconductor chip 20 and the metal layer 25. The stress buffer layer 22 is coated on the wafer for minimizing damage to the semiconductor chip 20 in the course of wire bonding (S200).

Subsequently, the wafer having the stress buffer layer 22 formed thereon is patterned by means of a prescribed masking process to realize the semiconductor chip 20 having the edge-bonding metal patterns 26, serving as the edge-bonding pads, on the wafer (S300).

The process for forming the edge-bonding metal patterns 26, serving as the edge-bonding pads, on the semiconductor chips 20 is the same as that according to the first preferred embodiment of the present invention, and therefore a detailed description thereof will not be given.

After the semiconductor chip 20 having the edge-bonding metal patterns 26 formed thereon is realized on the wafer as described above, the metal-patterned wafer is sawn by units of a prescribed semiconductor chip size by means of a blade (S400).

Subsequently, the first semiconductor chip 20 having the edge-bonding metal patterns 26 formed thereon, which is sawn by units of the prescribed semiconductor chip size, is attached to the substrate 10 having the circuit patterns 11 formed therein, which are formed in a prescribed shape for electric connection, by means of the bonding agent 60 (S500).

After the first semiconductor chip 20 is attached to the substrate 10 as described above, the edge-bonding metal patterns 26 formed on the first semiconductor chip 20 and the circuit patterns 11 formed in the substrate 10 are connected to each other by means of the connection members 30, i.e., the conductive wires so that the edge-bonding metal patterns 26 formed on the semiconductor chip 20 are electrically connected to the corresponding circuit patterns 11 formed in the substrate 10 at the edge regions of the semiconductor chip 20 (S600).

Subsequently, the nonconductive bonding member 70 having the spacer therein is applied to the first semiconductor chip 20 to realize a multi-layered BGA package (S700), and the second semiconductor chip 20′ is attached to the first semiconductor chip 20 via the nonconductive bonding member 70 so that the second semiconductor chip 20′ is stacked on the first semiconductor chip 20 (S800).

The nonconductive bonding member 70 having the spacers therein, which is disposed between the second semiconductor chip 20′ and the first semiconductor chip 20 mounted on the substrate 10, serves to maintain balance between the first semiconductor chip 20 and the second semiconductor chip 20′, and to prevent shorts between the second semiconductor chip 20′ and the connection members 30, i.e., the conductive wires of the first semiconductor chip 20.

After the second semiconductor chip 20′ is stacked on the first semiconductor chip 20 via the nonconductive bonding member 70 having the spacers therein as described above, the edge-bonding metal patterns 26 formed on the second semiconductor chip 20′ are electrically connected to the corresponding circuit patterns 11 formed in the substrate 10 at the edge regions of the second semiconductor chip 20′ by means of the second connection members 30′, i.e., the conductive wires (S900).

Subsequently, the substrate 10 is molded with the sealing material 40, for example, synthetic resin to protect the first and second semiconductor chips 20 and 20′ formed on the substrate 10 (S1000), and the solder balls 50 are attached to the conductive solder pads formed on the lower surface of the substrate 10 so that electric signals from the first and second semiconductor chips 20 and 20′ mounted on the substrate 10 are transmitted to an external substrate (S1100).

Finally, the packaged substrate molded with the sealing material 40 is sawn by units of a prescribed size to obtain a multi-layered BGA package having semiconductor chips with the edge-bonding metal patterns 26 formed thereon in a wafer level (S1200).

As apparent from the above description, the present invention provides a BGA package having center-bonding type semiconductor chips with edge-bonding metal patterns formed thereon in a wafer level wherein the edge-bonding metal patterns are formed on the semiconductor chips in the wafer level, and wire bonding is carried out in the shape of edge bonding, and a method of manufacturing the same. Consequently, the present invention has an effect of stacking a plurality of semiconductor chips, whereby the cost of the assembly process is reduced and high-density memory performance is obtained.

Also, the present invention has another effect of miniaturizing wire bonding pads for electrical connection since the edge-bonding metal patterns are formed on the semiconductor chips in a wafer level, whereby the number of semiconductor chips realized on the wafer is increased, and thus the cost of manufacturing semiconductor chips is reduced.

Furthermore, the present invention has still another effect of preventing disconnection of wires and short circuits generated in the course of wire bonding since the edge-bonding metal patterns are formed on the semiconductor chips in a wafer level, whereby reliability of the package is improved.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A ball grid array (BGA) package having a semiconductor chip with edge-bonding metal patterns formed thereon, comprising:
a substrate having circuit patterns for electric connection formed therein;
a center-bonding type semiconductor chip attached to the substrate, the semiconductor chip having center-bonding pads formed on one side thereof;
edge-bonding metal patterns electrically connected to the center-bonding pads of the semiconductor chip, the edge-bonding metal patterns being extended towards the edge regions of the center-bonding type semiconductor chip;
connection members for electrically connecting the edge-bonding metal patterns extended towards the edge regions of the semiconductor chip to the circuit patterns of the substrate, respectively;
a sealing material for molding the substrate to protect the semiconductor chip; and
solder balls attached to solder pads electrically connected to the circuit patterns of the substrate, respectively, for transmitting electric signals from the semiconductor chip to an external substrate.

2. A ball grid array (BGA) package having semiconductor chips with edge-bonding metal patterns formed thereon, comprising:
a substrate having circuit patterns for electric connection formed therein;
a first center-bonding type semiconductor chip attached to the substrate, the first semiconductor chip having center-bonding pads formed on one side thereof;
edge-bonding metal patterns electrically connected to the center-bonding pads of the first semiconductor chip, the edge-bonding metal patterns being extended towards the edge regions of the first center-bonding type semiconductor chip;
a bonding member applied to the first semiconductor chip to form a stacked structure;
a second center-bonding type semiconductor chip stacked on the first semiconductor chip via the bonding member, the second semiconductor chip having center-bonding pads formed on one side thereof;
edge-bonding metal patterns electrically connected to the center-bonding pads of the second semiconductor chip, the edge-bonding metal patterns being extended towards the edge regions of the second center-bonding type semiconductor chip;
connection members for electrically connecting the edge-bonding metal patterns of the first and second semiconductor chips to the circuit patterns of the substrate, respectively;
a sealing material for molding the substrate to protect the first and second semiconductor chips; and
solder balls attached to solder pads electrically connected to the circuit patterns of the substrate, respectively, for transmitting electric signals from the first and second semiconductor chips to an external substrate.

3. The package as set forth in claim 2, wherein the bonding member applied to the first semiconductor chip is a nonconductive bonding agent having spacers therein, the bonding member serving to maintain balance between the first semiconductor chip and the second semiconductor chip and to prevent shorts between the second semiconductor chip and the connection members of the first semiconductor chip.

4. The package as set forth in claim 1 or 2, wherein the metal patterns are formed by means of sputtering a conductive metal.

5. The package as set forth in claim 1 or 2, wherein the connection members are conductive wires.

6. The package as set forth in claim 1, wherein the edge-bonding metal patterns are connected to the corresponding circuit patterns of the substrate at the edge regions of the semiconductor chip by means of the connection members.

7. The package as set forth in claim 2, wherein the edge-bonding metal patterns are electrically connected to the corresponding circuit patterns of the substrate at the edge regions of the first and second semiconductor chips by means of the connection members, respectively.

8. The package as set forth in claim 1 or 2, wherein the sealing material is synthetic resin.

9. A method of manufacturing a ball grid array (BGA) package having a semiconductor chip with edge-bonding metal patterns formed thereon, comprising the steps of:
carrying out passivation of a wafer having a semiconductor chip with center-bonding pads formed thereon;
forming a stress buffer layer on the wafer to minimize damage to the semiconductor chip;
forming edge-bonding metal patterns on the semiconductor chip to change the center-bonding pads formed on the semiconductor chip into edge-bonding pads in a wafer level;
sawing the wafer having the edge-bonding metal pads formed thereon by units of a prescribed semiconductor chip size;
attaching the semiconductor chip to a substrate by means of a bonding agent;
electrically connecting the edge-bonding metal patterns formed on the semiconductor chip to circuit patterns formed in the substrate at edge regions of the semiconductor chip by means of connection members, respectively;
molding the substrate with a sealing material to protect the semiconductor chip;
attaching solder balls to solder pads electrically connected to the circuit patterns of the substrate, respectively, so that electric signals from the semiconductor chip are transmitted to an external substrate; and
sawing the substrate having the solder balls attached thereto to obtain a single-layered BGA package.

10. A method of manufacturing a ball grid array (BGA) package having semiconductor chips with edge-bonding metal patterns formed thereon, comprising the steps of:
carrying out passivation of a wafer having a semiconductor chip with center-bonding pads formed thereon;
forming a stress buffer layer on the wafer to minimize damage to the semiconductor chip;
forming edge-bonding metal patterns on the semiconductor chip to change the center-bonding pads formed on the semiconductor chip into edge-bonding pads in a wafer level;
sawing the wafer having the edge-bonding metal pads formed thereon by units of a prescribed semiconductor chip size;
attaching a first semiconductor chip to a substrate by means of a bonding agent;
electrically connecting edge-bonding metal patterns formed on the first semiconductor chip to circuit patterns formed in the substrate at edge regions of the first semiconductor chip by means of connection members, respectively;
applying a bonding member to the first semiconductor chip to form a stacked structure;
stacking a second semiconductor chip on the first semiconductor chip via the bonding member;
electrically connecting edge-bonding metal patterns formed on the second semiconductor chip to the circuit patterns formed in the substrate at edge regions of the second semiconductor chip by means of connection members, respectively;
molding the substrate with a sealing material to protect the first and second semiconductor chips;
attaching solder balls to solder pads electrically connected to the circuit patterns of the substrate, respectively, so that electric signals from the first and second semiconductor chips are transmitted to an external substrate; and
sawing the substrate having the solder balls attached thereto to obtain a multi-layered BGA package.

11. The method as set forth in claim 9 or 10, wherein the step of forming edge-bonding metal patterns on the semiconductor chip comprises:
coating a photoresist on the stress buffer layer formed on the wafer;
coating a mask having a mask pattern for opening the center-bonding pads of the semiconductor chip on the photoresist;
exposing the stress buffer layer and the photoresist on the unmasked regions;
developing the exposed regions to remove the stress buffer layer and the photoresist so that the center-bonding pads are opened;
exfoliating the photoresist on the masked regions and forming a metal layer to form edge-bonding metal patterns;
coating a photoresist on the metal layer;
coating a mask having a mask pattern for forming edge-bonding metal patterns on the photoresist;
exposing the photoresist on the unmasked regions;
removing the photoresist on the exposed regions and etching the metal layer under the removed photoresist; and
exfoliating the photoresist left on the regions protected by the mask to form edge-bonding metal patterns on the semiconductor chip.
